(19) United States
(12) Patent Application Publication
(10) Pub. No.: US 2018/0080997 A1
(43) Pub. Date: Mar. 22, 2018

(54) METHOD FOR TESTING BATTERY CYCLE LIFE BASED ON ENVIRONMENTAL TEMPERATURE

(71) Applicant: NIO NEXTEV LIMITED, Hong Kong (CN)

(72) Inventors: Shengjie YUAN, Shanghai (CN); Qi ZHANG, Shanghai (CN)

(21) Appl. No.: 15/710,467

(22) Filed: Sep. 20, 2017

(30) Foreign Application Priority Data
Sep. 21, 2016 (CN) 201610840205.X

(51) Int. Cl. G01R 31/36; H01M 10/48

(52) U.S. Cl. CPC G01R 31/3679; G01R 31/3627; H01M 10/486

(57) ABSTRACT

A method for testing battery cycle life based on environmental temperature is provided. The method comprises recording the daily average temperatures of a certain region in a year, categorizing the recorded daily average temperatures in the year, determining the proportion of the number of days of each temperature range to the total number of days in that year, determining the temperature conditions for the battery cycle life test according to the temperature ranges and thus determining the respective charge rates and discharge rates of the battery cycle life test according to the temperature conditions, and testing the battery according to the proportions, the temperature conditions and the charge and discharge rates under the temperature conditions to obtain the battery life cycle. With the above steps, the actual environmental temperatures of a battery can be accurately determined, and thereby precisely estimating the battery's lifespan.

### CROSS-REFERENCE TO RELATED APPLICATION

This application claims the benefit of China Patent Application No. 201610840205.X filed Sep. 21, 2016, the entire content of which is incorporated herein by reference.

### TECHNICAL FIELD

The present application relates to testing battery life, particularly to method for testing a battery cycle life based on environmental temperature.

### BACKGROUND

The cycle life test method of a power battery can be used for estimating its lifespan. The overall miles the electric vehicle can be driven and the power provided by the battery during the lifespan of the power battery are evaluated according to the test results and the available electricity and the change of output power of the battery during the test process.

Usually, the battery cycle life is tested at a constant environmental temperature (such as 25° C.), and the battery is charged at a constant current to its SOC upper limit, then discharged at a constant or variable current to its SOC lower limit. The battery cycle test is carried out in this way until the available capacity/power reaches a predetermined standard. However, the environmental temperature at which the battery works constantly changes, this battery cycle life test method is unable to accurately predict the real lifespan of a battery.

Accordingly, there is a need in the art for a new battery cycle life test method to resolve the above mentioned problems.

### SUMMARY OF THE APPLICATION

To address problems as above mentioned in the art, that is, the existing methods for testing battery cycle life are unable to accurately predict the actual lifespan of a battery, a method for testing a battery cycle life based on environmental temperature is provided. The method comprises the steps of: recording daily average temperatures of a certain region in a year; categorizing the recorded daily average temperatures in the year; determining the temperature conditions for testing the battery cycle life according to the categorized daily average temperatures in the year; determining electric current conditions for testing the battery cycle life according to the determined temperature conditions for testing the battery cycle life; and testing the battery cycle life according to the temperature conditions and the current conditions and recording the test results.

According to the method for testing battery cycle life based on environmental temperature, the step of categorizing the recorded daily average temperatures in the year further includes: recording the number of days of each preset temperature range; and determining the proportion of each temperature range to the whole year.

According to the method for testing battery cycle life based on environmental temperature, the step of determining the temperature conditions for testing the battery cycle life further includes: ranking the temperature ranges in the order from lower temperatures to higher temperatures; and determining a test temperature for each temperature range.

According to the method for testing battery cycle life based on environmental temperature, the step of determining the test temperature of each temperature range further includes: using the middle temperature value of each temperature range as the test temperature.

According to the method for testing battery cycle life based on environmental temperature, the step of determining the current conditions for testing the battery cycle life further includes: determining corresponding charge rates and discharge rates in testing the battery cycle life according to the test temperatures.

By an example, the span of the preset temperature ranges is 10° C. according to the method for testing battery cycle life based on environmental temperature.

According to the method for testing battery cycle life based on environmental temperature, the step of determining corresponding charge rates and discharge rates in testing the battery cycle life according to the test temperatures is achieved on the following conditions: when the temperature range is −30≦T<−20, the test temperature is −25° C., the charge rate is 0.1 C and the discharge rate is 0.3 C; or when the temperature range is −20≦T<−10, the test temperature is −15° C., the charge rate is 0.2 C and the discharge rate is 0.3 C; or when the temperature range is −10≦T<0, the test temperature is −5° C., the charge rate is 0.2 C and the discharge rate is 0.3 C; or when the temperature range is 0≦T<10, the test temperature is 5° C., the charge rate is 0.3 C and the discharge rate is 0.3 C; or when the temperature range is 10≦T<20, the test temperature is 15° C., the charge rate is 0.3 C and the discharge rate is 0.5 C; or when the temperature range is 20≦T<30, the test temperature is 25° C., the charge rate is 0.5 C and the discharge rate is 1 C; or when the temperature range is 30≦T<40, the test temperature is 35° C., the charge rate is 0.5 C and the discharge rate is 1 C; or when the temperature range is 40≦T<50, the test temperature is 45° C., the charge rate is 0.5 C and the discharge rate is 0.5 C.

According to the method for testing battery cycle life based on environmental temperature, the step of testing the battery cycle life and recording the test results includes: charging/discharging the battery to its upper limit/lower limit each time.

According to the method for testing battery cycle life based on environmental temperature, the battery is power battery of electric vehicles.

As can be appreciated by those skilled in the art, in the optimized technical solutions of this application, the daily average temperatures of a region in a year are recorded and divided into several ranges; the number of days of each range is counted and therefore its proportion to the total number of days in this year is calculated; the temperature conditions for the battery cycle life test is acquired for each of the ranges so as to further acquire the respective charge-discharge rates of the battery cycle life test according to the temperature conditions; and the battery is tested under the battery cycle life test conditions acquired according to the proportions, the temperature conditions and the charge-discharge rates. With the above solution, this application can accurately reflect the actual working conditions of a battery so as to precisely estimate the distance that the vehicle can be driven and therefore bring benefit to vehicle research and development.

### BRIEF DESCRIPTION OF THE DRAWINGS

FIG. 1 is a flow chart of method for testing a battery cycle life of the present application;

FIG. 2 is a table showing test temperatures according to the method for testing the battery cycle life;

FIG. 3 is a table showing test currents according to the method for testing battery cycle life;

FIG. 4 is a table showing temperatures of Shanghai in 2015;

FIG. 5 shows the number of days of each temperature range and its proportion to the total number of days of Shanghai in that year;

FIG. 6 is a table in which the temperature conditions according to the method for testing battery cycle life are shown; and

FIG. 7 is a table in which the cycle life conditions according to the method for testing the battery cycle life are shown.

### DETAILED DESCRIPTION

The preferred embodiments of the present application will be described below with reference to the accompanying figures. As will be understood by those skilled in the art, these embodiments are merely used for interpreting the technical principle of the present application and are not intended to limit its protection scope in any way. For example, although the detailed description of the present application is specifically provided based on the temperature of 2015 in Shanghai, it is obvious that the method for testing battery cycle life based on environmental temperature of the present application is suitable for use in any regions, all these can be modified by those skilled in the art as desired to accommodate specific applications.

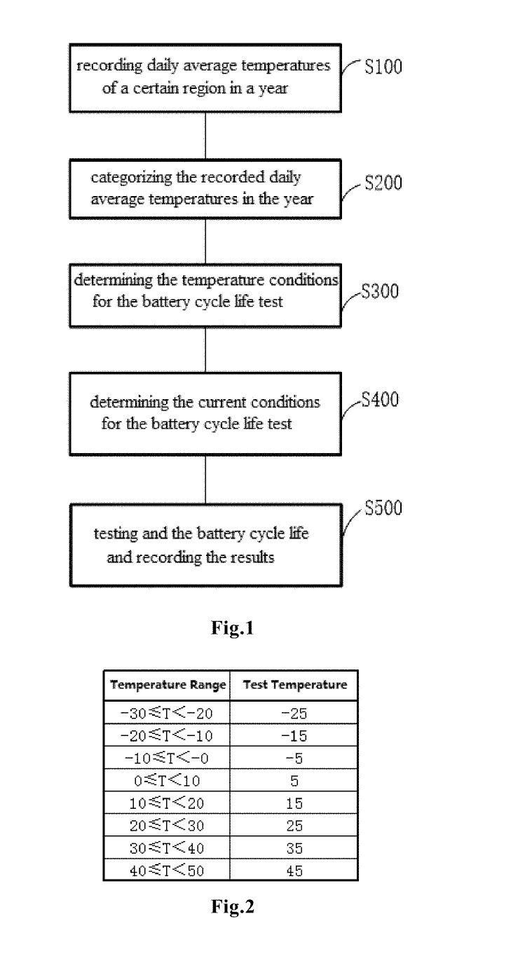

As shown in FIG. 1, the method for testing battery cycle life based on environmental temperature of the present application comprises the following steps:

At step S100, the average temperatures of every day of a year are recorded. It is necessary to record the average temperatures of every day in different regions separately due to the differences in their temperatures, in which regions described herein can be construed as a collection of areas with minor daily average temperature differences (no higher than 2° C.). Then, the average temperatures of every day of a year are calculated based on the recorded daily average temperatures in different regions. To ensure the accuracy of the daily average temperature of different regions in a year, the reference can be made only to the daily average temperatures of different regions in recent years (for example, in last year, in past three years or in past five years, etc.).

At step S200, the recorded daily average temperatures of each region in a year are divided according to its temperature value into several temperature ranges. Also, the proportion of the number of days of each temperature range to the total number of days in that year can be determined. As shown in FIG. 2, for example when each temperature range is of 10° C. temperature span, the number of days of each temperature range and its proportion to the total number of days in this year are accordingly obtained. It should be understood by those skilled in the art that, the temperature span is not limited to 10° C. but variable correspondingly for different regions or target test accuracies.

At step S300, as shown in FIG. 2, the temperature ranges recorded and divided at the step of S200 are ranked in order of temperature from low to high. And, the middle temperature value within each temperature range is used as the test temperature value, i.e., the temperature conditions for testing the battery cycle life are determined. As can be understood by those skilled in the art, it is merely exemplary to choose these middle temperature values as the test temperature values, the most frequently appeared daily average temperature value within each range or the temperature value which is close to most daily average temperature values in the range can be used as the test temperature value of this range in order to obtain more accurate test results.

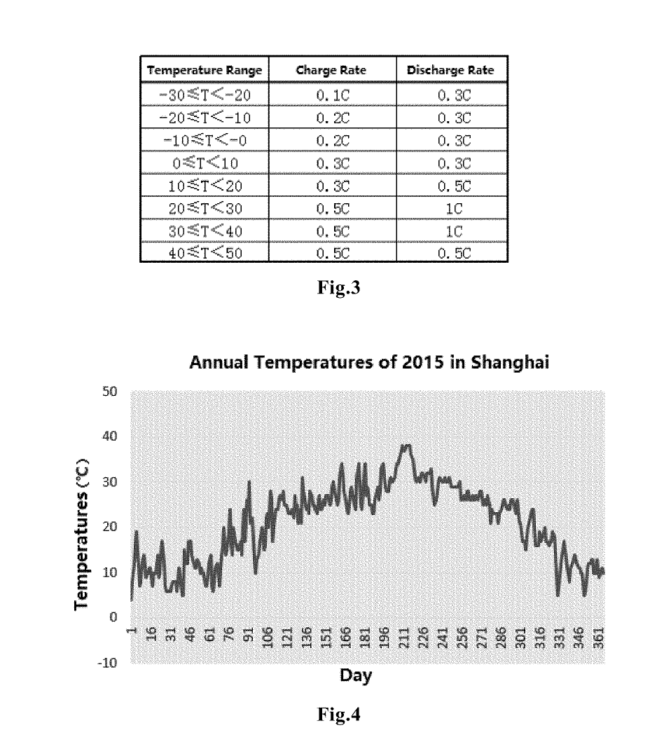

At step S400, the charge-discharge rates, i.e., the charge-discharge current magnitudes, are determined according to the temperature conditions acquired at the step of S300. It should be understood by those skilled in the art that when a battery is charged in a low temperature environment, bigger current will lead to precipitate of lithium due to raised resistance; when a battery works in a high temperature environment, the heat within the battery is not easy to dissipate which may result in battery overheating. In consideration of the discharge power of the electric vehicle battery, the battery should be charged or discharged with different test currents at different test temperatures. For example, the charge-discharge rates of the battery at different test temperatures (or in different temperature ranges) are shown in FIG. 3.

At step S500, according to the proportion of the number of days of each range to the total number of days in this year recorded in the step of S200, the temperature conditions determined in the step of S300 and the working conditions of charge-discharge rates determined in the step of S400, the charge-discharge rates of testing the battery cycle life are determined. Moreover, tests of battery cycle life are carried out according to the determined charge-discharge rates, and the results of each test are recorded, and the battery's actual lifespan is therefore predicted.

By an example, a cycle life test of an electric vehicle's power battery which is carried out based on the atmospheric temperatures of Shanghai in 2015 is described hereinafter.

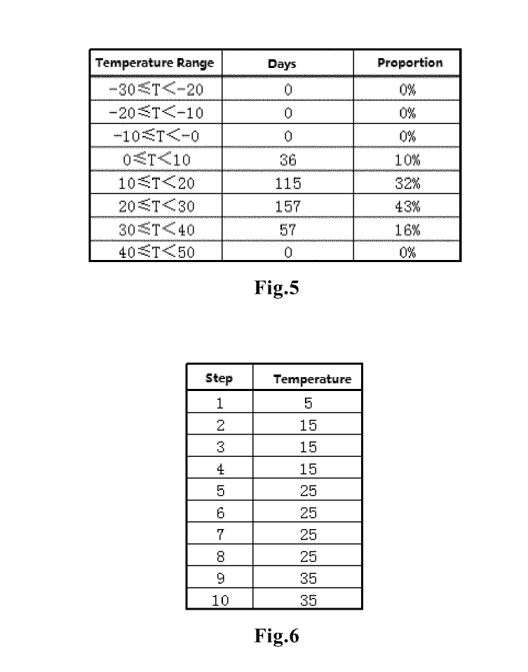

FIG. 4 is a table showing the daily average temperature of Shanghai in 2015. It can be seen from the table that big temperature fluctuations happened in the first half of year 2015. The daily average temperature fluctuations between adjacent periods of time, however, are substantially in range of 10° C., the daily average temperatures of Shanghai in 2015 are thus divided into several ranges with temperature span being 10° C. As shown in FIG. 5, the number of days fallen into each range is recorded, the recorded number of days of each range is divided by the total number of days in this year to get the proportion of the recorded number of days of this range to the total number of days in this year. Specifically, there is about 10% of the total number of days of this year falling into the 0≦T<10 temperature range, there is about 32% of the total number of days of this year falling into the 10≦T<20 temperature range, there is about 43% of the total number of days of this year falling into the 20≦T<30 temperature range, there is about 16% of the total number of days of this year falling into the 30≦T<40 temperature range, and the number of days with average temperature falling into other ranges is zero.

As shown in FIG. 6, the middle temperature value of each range is used as the test temperature value. That is to say, the middle temperature value for the range 0≦T<10 is 5° C., the middle temperature value for the range 10≦T<20 is 15° C., the middle temperature value for the range 20≦T<30 is 25° C., and the middle temperature value for the range 30≦T<40 is 35° C. With equally dividing the days in 2015 into 10 groups and on the basis of the proportions of recorded number of days of each range to the total number of days in year 2015, one of these groups has the test temperature value of 5° C., other three have the test temperature value of 15° C., other four have the test temperature value of 25° C., and other two have the test temperature value of 35° C. Further, these groups are ranked in order of temperature from low to high, and the temperature conditions of testing of the battery cycle life and the proportions of the battery being tested at these temperature conditions are acquired.

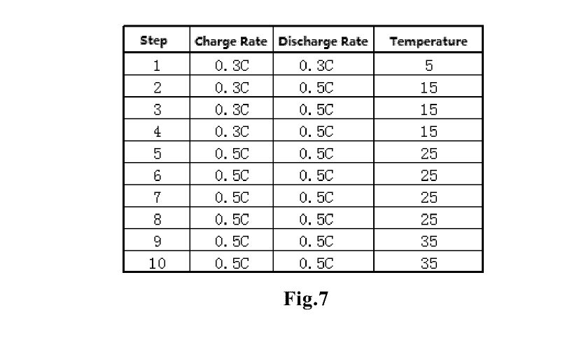

As shown in FIG. 7, the charge-discharge rates of the battery are determined according to the temperatures of the battery cycle life test shown in FIG. 6. Then, the battery can be charged and discharged in the order of steps shown in FIG. 7 according to the proportions, temperature conditions and charge-discharge rates. It should be noted that, the duration of each step of steps 1 to 10 are the same.

It should be understood by those skilled in the art that, except taking the middle temperature value in each range as a test temperature value, it is also possible to use several temperature values in each range as test temperature values. When testing, the present test temperature of the current range can be changed from one to another of these temperature values according to local climate change, so as to improve the accuracy of the battery cycle life test result.

It can also be understood by those skilled in the art that during the testing of the battery cycle life, the battery is always charged up to its SOC upper limit when charging and always discharged to its SOC lower limit when discharging.

So far, the technical solutions of the present application have been described with reference to the preferred embodiments shown in the accompanying figures. As will be appreciated by those skilled in the art, however, these specific embodiments are not intended to limit protection scope of the application. It will be understood by those skilled in the art that, without departing from the principle of the application, various changes may be made and equivalents may be substituted for related technical features, the varied or substituted technical solutions will fall within protection scope of the application.

What is claimed is:

1. A method for testing battery cycle life based on environmental temperature, comprising:
recording daily average temperatures of a certain region in a year;
categorizing the recorded daily average temperatures in the year;
determining the temperature conditions for testing the battery cycle life according to the categorized daily average temperatures in the year;
determining electric current conditions for testing the battery cycle life according to the determined temperature conditions for testing the battery cycle life; and
testing the battery cycle life according to the temperature conditions and the electric current conditions and recording the testing results.

2. The method for testing battery cycle life based on environmental temperature according to claim 1, wherein the step of categorizing the recorded daily average temperatures in the year further includes:
recording the number of days of each preset temperature range; and
determining the proportion of each temperature range to the whole year.

3. The method for testing battery cycle life based on environmental temperature according to claim 2, wherein the step of determining the temperature conditions for testing the battery cycle life further includes:
ranking the temperature ranges in order of temperature from low to high; and
determining a test temperature for each temperature range.

4. The method for testing battery cycle life based on environmental temperature according to claim 3, wherein the step of determining the test temperature for each temperature range further includes:
using the middle temperature value in each temperature range as the test temperature.

5. The method for testing battery cycle life based on environmental temperature according to claim 4, wherein the step of determining the electric current conditions for testing the battery cycle life further includes:
determining corresponding charge rates and discharge rates in testing the battery cycle life according to the test temperatures.

6. The method for testing battery cycle life based on environmental temperature according to claim 5, wherein the span of the preset each temperature range is 10° C.

7. The method for testing battery cycle life based on environmental temperature according to claim 6, wherein the step of determining corresponding charge rates and discharge rates in testing the battery cycle life according to the test temperatures is achieved on the following conditions:
when the temperature range is −30≦T<−20, the test temperature is −25° C., the charge rate is 0.1 C, and the discharge rate is 0.3 C; or
when the temperature range is −20≦T<−10, the test temperature is −15° C., the charge rate is 0.2 C, and the discharge rate is 0.3 C; or
when the temperature range is −10≦T<0, the test temperature is −5° C., the charge rate is 0.2 C, and the discharge rate is 0.3 C; or
when the temperature range is 0≦T<10, the test temperature is 5° C., the charge rate is 0.3 C, and the discharge rate is 0.3 C; or
when the temperature range is 10≦T<20, the test temperature is 15° C., the charge rate is 0.3 C, and the discharge rate is 0.5 C; or
when the temperature range is 20≦T<30, the test temperature is 25° C., the charge rate is 0.5 C, and the discharge rate is 1 C; or
when the temperature range is 30≦T<40, the test temperature is 35° C., the charge rate is 0.5 C, and the discharge rate is 1 C; or
when the temperature range is 40≦T<50, the test temperature is 45° C., the charge rate is 0.5 C, and the discharge rate is 0.5 C.

8. The method for testing battery cycle life based on environmental temperature according to claim 1, wherein the step of testing the battery cycle life and recording the test results includes: charging the battery to its upper limit when charging and discharging the battery to its lower limit when discharging.

9. The method for testing battery cycle life based on environmental temperature according to claim 8, wherein the battery is power battery of electric vehicles.
